(19) United States
(12) Patent Application Publication
(10) Pub. No.: US 2005/0164472 A1
(43) Pub. Date: Jul. 28, 2005

(54) Method for separating electronic components from a composite

(76) Inventors: Volker Brod, Bad Abbach (DE); Ludger Overmeyer, Bordenau (DE); Hans-Peter Monser, Dresden (DE)

Correspondence Address: Timothy E Newholm;Boyle Fredrickson Newholm Stein & Gratz, 250 Plaza, Suite 1030, 250 East Wisconsin Avenue, Milwaukee, WI, 53202, US

(21) Appl. No.: 10/474,644

(22) PCT Filed: Apr. 10, 2002
(86) PCT No.: PCT/EP02/04001

(30) Foreign Application Priority Data
Apr. 10, 2001 (DE) 101 17 880.8

(51) Int. Cl. H01L 21/301; H01L 21/46; H01L 21/78

(52) U.S. Cl. 438/460; 438/464

(57) ABSTRACT

The invention relates to a method of singulating thin chips from a sawn wafer, comprising the steps of glueing the wafer first onto a carrier and sawing it then into individual chips on said carrier. Subsequently, the chips are detached from the carrier individually or in groups. The method is so conceived that carrier is a rigid board and the adhesive is heat-soluble, the adhesive being deactivated with the aid of heat passing either through the chip itself or through the carrier prior to the detachment of said chips, whereupon the respective chip is detached.

The invention relates to a method of singulating electronic components from a composite structure, in particular chips from a wafer, wherein the composite structure is first glued onto a carrier and the components are separated from one another, whereupon the components are detached from the carrier individually or in groups making use of a vacuum pipette, the adhesive effect of the adhesive being adapted to be reduced selectively, the adhesive effect of said adhesive being reduced in the area in question prior to or during the detachment of the components.

The course of action that has been adopted up to now is that wafers are applied to an elastic carrier film. Subsequently, these wafers are separated into individual chips in a sawing process. This sawn wafer on the carrier film defines together with a support frame the starting material for the so-called die bonding processes. For detaching the chips from the carrier film, a needle, the so-called die ejector, is first moved, from the back, to a position below the chip to be detached; this die ejector detaches the chip from the carrier film from below. The thus detached chip is picked up by a vacuum pipette and transferred to another substrate, where the chip is then subjected to further processes. JP-A-2039452, for example, discloses a method wherein, in addition to the above-mentioned features, the adhesive of the carrier material is weakened by the influence of a heat source, so as to improve chip detachment.

This method proved to be very useful in the past; a prerequisite for this method is, however, that the chip is comparatively rigid in comparison with the carrier film, so that the ejector needle acting from the back will stretch the carrier film but nevertheless raise the chip.

It is the object of the present invention to provide a method with the aid of which also thinner chips can be singulated, i.e. also chips whose own behaviour is similar to that of a film.

These are especially silicon chips having a thickness of less than 60 μm down to a thickness of 10 μm.

For achieving this object, the method according to the present invention is so conceived that the carrier is implemented as a rigid board, preferably a board of glass, glass ceramics or plastic material, the adhesive being deactivated in the respective area of the composite structure prior to the detachment of the components, and the component in question being picked up exclusively by means of the vacuum pipette.

This method is advantageous insofar as, just as in the case of the hitherto known methods, vacuum pipettes can still be used for the purpose of detaching and insofar as it is additionally possible to detach also thin chips, which have a high ductility and whose behaviour is similar to that of a film, in an easy manner without using a die ejector. The carrier can comprise a rigid board, preferably a board of glass, glass ceramics or plastic material. Especially in cases where the heat is supplied through the carrier, it will be advantageous when the thermal conductivity of the carrier is better in a direction transverse to the carrier plane than in the direction of the carrier plane. Materials, especially glass ceramics, having these properties are known to a sufficient extent; they are used e.g. for ceramic hobs. It also proved to be advantageous when the adhesive is implemented as a film. This will guarantee a uniform thickness of the adhesive on the carrier.

The carrier comprises a rigid board, preferably a board of glass, glass ceramics or plastic material. Especially in cases where the heat is supplied through the carrier, it will be advantageous when the thermal conductivity of the carrier is better in a direction transverse to the carrier plane than in the direction of the carrier plane. Materials, especially glass ceramics, having these properties are known to a sufficient extent; they are used e.g. for ceramic hobs. It also proved to be advantageous when the adhesive is implemented as a film. This will guarantee a uniform thickness of the adhesive on the carrier. In this respect, it will be particularly advantageous when the selectively deactivated adhesive is heat soluble. It will then be particularly simple to deactivate the adhesive in a specific area of the composite structure by a purposeful application of heat, so as to detach the individual components subsequently. In the case of particularly thin components, the heat used for deactivating the adhesive can be applied through the respective component.

Alternatively, the heat for deactivating the adhesive can also be applied through the carrier. This possibility will be useful e.g. in cases where the components are not extremely thin or in cases where they are heat-sensitive. A simple possibility of applying the heat is the use of hot air. It will, however, also be advantageous to apply the heat by heat radiation, e.g. by infrared or laser irradiation.

The electronic components are preferably silicon chips having a thickness of from 10 μm to 60 μm.

In the following, the method will be explained in detail making reference to a drawing, in which:

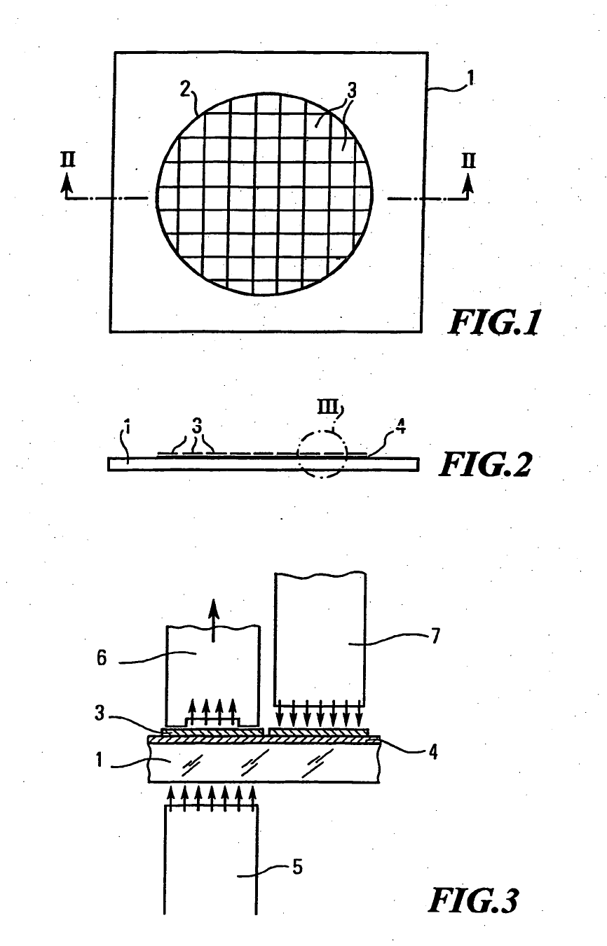

FIG. 1 shows a top view of a sawn wafer on a carrier board,

FIG. 2 shows a sectional view through the carrier board of FIG. 1 along line II-II, and

FIG. 3 shows an enlarged view of a detail of FIG. 2 with a schematic representation of two heat sources and of a vacuum pipette.

FIG. 1 shows a glass board 1 used as a carrier board for an already sawn wafer 2 which comprises a plurality of chips 3 that have already been separated from one another. Said wafer and chips, respectively, have a thickness of less than 60 μm and a behaviour similar to that of a film.

As can be seen even more clearly from FIG. 3, the wafer 2 is glued onto the glass board 1 with the aid of an adhesive film 4. The adhesive film 4 is made of a heat-soluble adhesive, i.e. an adhesive which loses or strongly reduces its adhesive properties when heated.

In the following, the method according to the present invention will be explained in detail making reference to the drawing.

The glass board 1 has first applied thereto an adhesive film 4. The wafer 2 in its entirety is then glued onto this adhesive film 4. Alternatively, it is also possible to glue the adhesive film first onto the wafer 2 which is then glued onto the glass board with the adhesive film 4.

Following this, the wafer 2 on the glass board 1 is separated into the individual chips 3. This is done in the usual way by sawing.

For singulating the individual chips 3, i.e. for detaching them, the adhesive film 4 is heated in the area of the wafer 2 from which the individual chip 3 is to be removed. In FIG. 3, two different methods are shown for this purpose. In the left half of FIG. 3, the lower surface of the glass board 1 is heated by means of a radiation source 5 below the chip 3 to be removed. In this area, the adhesive film 4 will dissolve so that the chip can be picked up and removed with the aid of a conventional vacuum pipette 6.

In the right half of FIG. 3, an alternative is shown. The heat is here applied from above, in this case with the aid of a hot-air nozzle 7, which is positioned above chip 3 to be removed. The heat penetrates the chip 3 and dissolves the adhesive of the adhesive film 4 therebelow. The hot-air nozzle 7 is then displaced to the side, thus making room for the vacuum pipette 6, which will then pick up the chip in the usual way.

The chips removed by means of the vacuum pipette 6 can be subjected to further processing in the usual way, e.g. glued onto some other substrate or subjected to further processing in a subsequent die-bonding process.

Alternatively to the above-described method, it is also possible to heat a large-area region of the carrier so that the adhesive will be de-activated in the area of a plurality of chips simultaneously.

1. A method of singulating electronic components from a composite structure, in particular chips from a wafer, wherein the composite structure is first glued onto a carrier and the components are separated from one another, whereupon the components are detached from the carrier individually or in groups making use of a vacuum pipette, the adhesive effect of the adhesive being adapted to be reduced selectively, the adhesive effect of said adhesive being reduced in the area in question prior to or during the detachment of the components, wherein the carrier is implemented as a rigid board, preferably a board of glass, glass ceramics or plastic material, the adhesive being deactivated in the respective area of the composite structure prior to the detachment of the components, and the component in question being picked up exclusively by means of the vacuum pipette.

2. A method according to claim 1, wherein the adhesive is heat-soluble.

3. A method according to claim 1, wherein the heat used for deactivating the adhesive is applied such that it passes through the component.

4. A method according to claim 1, wherein the heat used for deactivating the adhesive is applied such that it passes through the carrier.

5. A method according to claim 1, wherein the heat is applied by means of hot air.

6. A method according to claim 1, wherein the heat is applied by heat radiation.

7. A method according to claim 1, wherein the thermal conductivity of the carrier is better in a direction transverse to the carrier plane than in the direction of the carrier plane.

8. A method according to claim 1, wherein the electronic components are silicon chips having a thickness of from 10 μm to 60 μm.

9. A method of singulating electronic components from a composite structure, in particular chips from a wafer, wherein the composite structure is first glued onto a carrier, preferably a carrier made of glass, glass ceramics or plastic material, by means of a heat-soluble adhesive, and the electronic components are then separated from one another, whereupon the adhesive effect of the adhesive is eliminated by heat application, and the electronic components are subsequently removed one by one from the carrier by using exclusively a vacuum pipette, wherein prior to removing an electronic component from the composite structure by means of the vacuum pipette, the adhesive effect of the adhesive is eliminated exclusively in the respective area of said electronic component.

10. A method according to claim 9, wherein the adhesive is deactivated in the respective area of the electronic component.

11. A method according to claim 9, wherein the behaviour of the electronic components is similar to that of a film.

12. A method according to claim 10, wherein the heat used for deactivating the adhesive is applied such that it passes through the electronic component.

13. A method according to claim 10, wherein the heat used for deactivating the adhesive is applied such that it passes through the carrier.

14. A method according to claim 9, wherein the heat is applied by means of hot air.

15. A method according to claim 9, wherein the heat is applied by heat radiation.

16. A method according to claim 9, wherein the thermal conductivity of the carrier is better in a direction transverse to the carrier plane than in the direction of the carrier plane.

17. A method according to claim 9, wherein the electronic components are silicon chips having a thickness of from 10 μm to 60 μm.

18. A method according to claim 9, wherein no die ejector is used.
